(19) United States
(12) Patent Application Publication
(10) Pub. No.: US 2012/0052610 A1
(43) Pub. Date: Mar. 1, 2012

(54) Total internal reflection energy/heat source

(76) Inventor: Gabriel James Tambunga, Philadelphia, PA (US)

(21) Appl. No.: 13/136,993

(22) Filed: Aug. 17, 2011

Related U.S. Application Data
(60) Provisional application No. 61/402,540, filed on Sep. 1, 2010.

(51) Int. Cl. H01L 31/18

(52) U.S. Cl. 438/57; 257/E31.002

(57) ABSTRACT

The Total Internal Reflection Energy/Heat Source includes an object that allows electromagnetic radiation or phonons to be in total internal reflection within the object. The object, such as a microparticle or optical fiber, is doped with atoms or molecules that convert the electromagnetic radiation or phonons to heat, where the heat is transferred out of the object or converted to electricity. A second embodiment of the Total Internal Reflection Energy/Heat Source includes an object that allows electromagnetic radiation or phonons to be in total internal reflection within the object. The object, such as a microparticle, contains P-type and N-type materials beneath the surface, where the electromagnetic radiation or phonons in total internal reflection strikes the P-N junction of the P-type and N-type materials creating electricity.

### BACKGROUND OF THE INVENTION

1. Field of Invention

The present invention relates generally to the use of total internal reflection in a material to generate heat or electricity.

2. Discussion of Prior Art

Total internal reflection has been used as part of industry and research such as the fiber optic and the microparticle, respectively.

According to Jeff Hecht, City of Light: The Story of Fiber Optics, Oxford University Press 1999, impurities were in the fiber optic were known to reduce the energy transmitting through a fiber optic in Total Internal Reflection. Impurities were reduced to in the fiber optic to reduce the loss of energy.

According to L. M. Folan et al, Enhanced Energy Transfer within a Microparticle, Chemical Physics Letters, Volume 118, Number 3, 26 Jul. 1985 and S. Arnold et al, Energy Transfer and the Photon Lifetime Within an Aerosol Particle, Optics Letters, Vol. 14, No. 8, Apr. 15, 1989, impurities in small water droplets allow for the lifetime of photons (electromagnetic radiation) to be increased. The increase of lifetime of electromagnetic radiation in a microparticle will be considered as Total Internal Reflection in a microparticle in this invention for simplification.

It appears the prior art does not teach or suggest the use of Total Internal Reflection as a heat or energy source. Specifically, the prior art does not teach or suggest the re-introduction of impurities or further impurities in a fiber optic or microparticle to generate heat or energy by the transfer of energy from photon to the impurities. Though Solar Technology is an option for a clear need for alternative energy, Solar Technology is limited to its use in daytime. The Total Internal Reflection Energy/Heat Source offers an option during fewer times of less electromagnetic radiation during a 24 hour period in that photons/phonons will be trapped in Total Internal Reflection causing a greater chance of photons/phonons to be transferred to useful usable energy, or material involved in the Total Internal Reflection can be made to work with electromagnetic radiation that are available during night hours.

### REFERENCES CITED

### Other Publications

Hecht, Jeff: City of Light: The Story of Fiber Optics, Oxford University Press 1999

Folan, L. M.; Arnold, S.; and Druger, S. D.: Enhanced Energy Transfer within a Microparticle, Chemical Physics Letters, Volume 118, Number 3, Jul. 26, 1985

Arnold, S.; and Folan, L. M.: Energy Transfer and the Photon Lifetime Within an Aerosol Particle, Optics Letters, Vol. 14, No. 8, Apr. 15, 1989.

### SUMMARY OF THE INVENTION

The present invention uses total internal reflection of electromagnetic radiation or phonons in a material to create heat or electricity. The material is a solid, and in a shape and contains properties that causes the electromagnetic radiation or phonons to be in total internal reflection, such as a microparticle or optical fiber. The material is doped with atoms or molecules that convert some of the energy of the electromagnetic radiation or phonons to vibrations or heat, when struck by a photon or phonon. The heat is transferred out of the material by a mechanism that pulls (or pushes) the heat out or a mechanism that converts the heat directly to electricity.

A second embodiment uses total internal reflection of electromagnetic radiation or phonons in a material with a P-N junction to create electricity. The material is a solid, and in a shape and contains properties that causes the electromagnetic radiation or phonons to be in total internal reflection, such as a microparticle. The material contains a P-type and N-type material that are flushed against each other. The formed P-N junction constitutes the majority of the volume of the P-type and N-type materials when merged together, to allow the electromagnetic radiation or phonons in total internal reflection to easier penetrate to the P-N junction to create electricity.

Accordingly, it is an object of the present invention to use total internal reflection in a material to create heat or electricity.

These and additional objects, advantages, features and benefits of the present invention will become apparent from the following specifications.

### BRIEF DESCRIPTION OF THE DRAWINGS

FIG. 1 is a side cross sectional view of a microparticle containing dopants that will transfer energy from photons to heat.

FIG. 2 is a side cross sectional view of an optical fiber containing dopants that will transfer energy from photons to heat.

FIG. 3 is a side cross sectional view of a microparticle containing dopants that will transfer energy from photons to a P-N Junction where electricity will be generated.

### DETAILED DESCRIPTION OF PREFERRED EVENTS

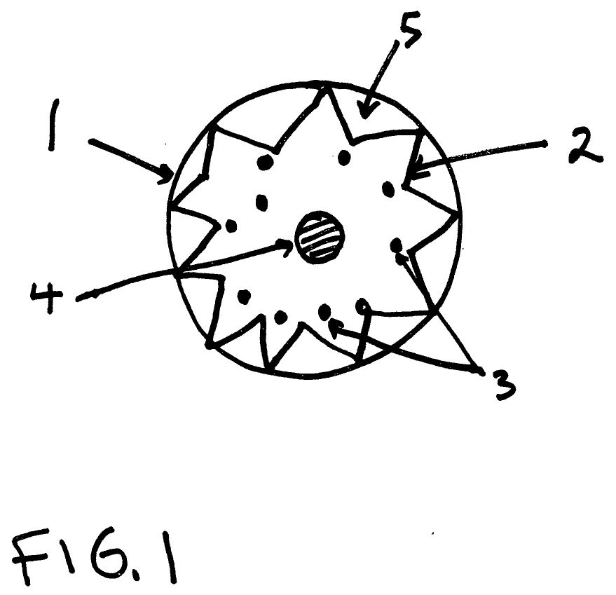

With reference now to the drawings, and particularly to FIG. 1, there is shown a cross sectional view of a microparticle 1 with electromagnetic radiation or phonon under total internal reflection 2 within microparticle 1. The microparticle 1 is composed of material 5 that allows electromagnetic radiation or phonons to be in total internal reflection 2. The microparticle 1 contains dopants 3 that convert the energy of electromagnetic radiation to vibrational energy or heat. The dopants 3 are immediately at or beneath the lowest point of reflection of the electromagnetic radiation in total internal reflection 2. The heat generated within the microparticle 1 is transferred out of the microparticle 1 by a mechanism 4 that converts heat to electricity or a mechanism that pulls or pushes out the heat.

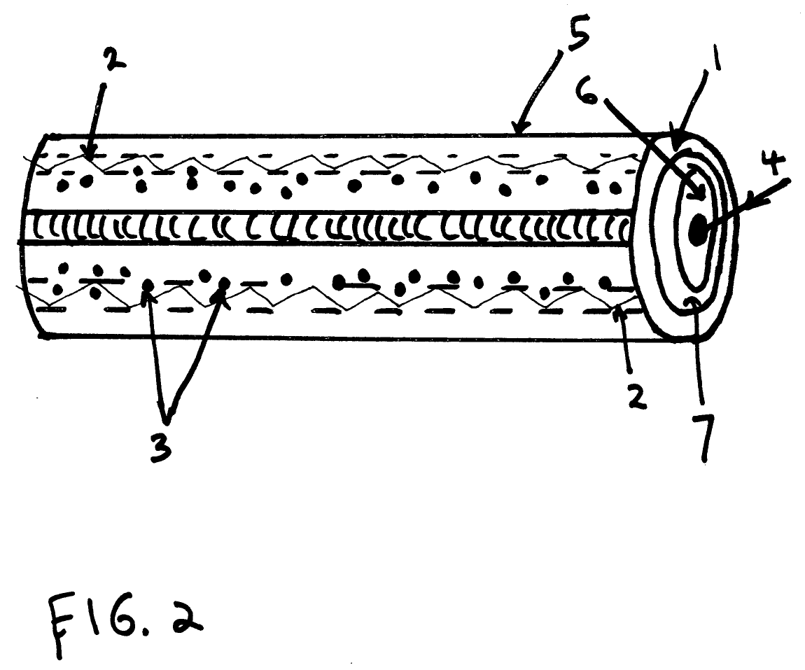

With reference now to the drawings, and particularly to FIG. 2, there is shown a cross sectional view of an optical fiber 5 with electromagnetic radiation or phonon under total internal reflection 2 within optical fiber 5. The optical fiber 5 contains dopants 3 that convert the energy of electromagnetic radiation to vibrational energy or heat. The dopants 3 are contained within material 6, which is immediately at or beneath the lowest point of reflection of the electromagnetic radiation in total internal reflection 2. The heat generated within the optical fiber 5 is transferred out of the optical fiber 5 by a mechanism 4 that converts heat to electricity or a mechanism that pulls or pushes out the heat. The index of refraction of materials 1 and 6 are different than the index of refraction of material 7 in a way that causes the electromagnetic radiation to be in total internal reflection 2 in material 7. An example would be the index of refraction of material 1 and material 6 being equal and lower than the index of refraction of material 7.

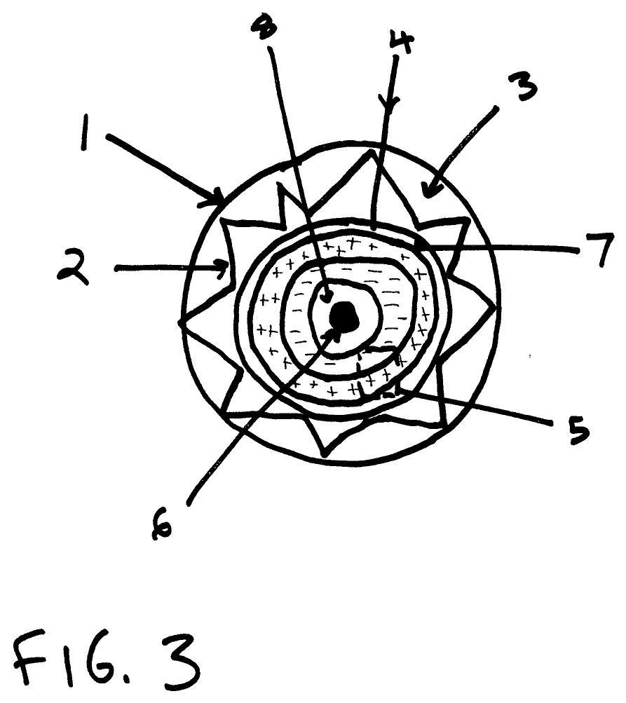

With reference now to the drawings, and particularly to FIG. 3, there is shown a cross sectional view of a microparticle 1 with electromagnetic radiation or phonon under total internal reflection 2 within microparticle 1. The microparticle 1 is composed of material 3 that allows electromagnetic radiation or phonons to be in total internal reflection 2. Immediately beneath material 3 is an N-type material 4 followed by a P-type material 8. A P-N junction 5 forms at the P-N interface, which encompasses most of the volume of the P-type material 8 and N-type material 4. The electrons exit a contact 7 to the N-type material 4 where there is no P-N junction 5. Holes exit through a contact 6 of the P-type material 8 where there is no P-N junction. The electrons and holes are created by the electromagnetic radiation in total internal reflection 2 striking the P-N junction 5.

While particular embodiments of the invention have been shown and described, it will be obvious to those skilled in the art that changes and modifications may be made without departing from the invention in its roader aspects, and therefore, the aim in the appended claims is to cover some changes and modifications as fall within the true spirit and scope of the invention.

I claim:

1. A method of generating heat or electricity, comprising the steps of:
providing a substance that allows Total Internal Reflection for a specific wavelength(s) or specific phonon frequency(ies) in a microparticle;
applying dopants to the said substance that converts the said specific wavelength(s) or said specific phonon frequency(ies); and
providing a means for the said heat or said electricity to leave the said microparticle.

2. A method of generating heat or electricity, comprising the steps of:
providing substances that allow Total Internal Reflection for a specific wavelength(s) or specific phonon frequency(ies) in an optical fiber;
applying dopants to the said substances that converts the said specific wavelength(s) or said specific phonon frequency(ies); and
providing a means for the said heat or said electricity to leave the said optical fiber.

3. A method of generating electricity, comprising the steps of:
providing a substance that allows Total Internal Reflection for a specific wavelength(s) or specific phonon frequency(ies) in a microparticle;
providing substances that allow for a P-N junction to be surrounded by the said substance that allows said Total Internal Reflection for the said specific wavelength(s) or the said specific phonon frequency(ies) in the said microparticle; and
providing a means for the said heat or said electricity to leave the said microparticle as is created when the P-N junction is struck by the said specific wavelength(s) or said specific phonon frequency(ies).
